(19) United States
(12) Patent Application Publication
(10) Pub. No.: US 2025/0343219 A1
(43) Pub. Date: Nov. 6, 2025

(54) THREE-DIMENSIONAL INTEGRATED CIRCUITS AND METHODS OF FORMING

(71) Applicant: Taiwan Semiconductor Manufacturing Co., Ltd., Hsinchu (TW)

(72) Inventors: Chung-Hui Chen, Hsinchu (TW); Chin-Ming Fu, Hsinchu (TW); Pei-Chieh Lin, Hsinchu (TW); Hui-Mei Chou, Hsinchu (TW)

(21) Appl. No.: 19/267,382

(22) Filed: Jul. 11, 2025

Related U.S. Application Data
(63) Continuation of application No. 18/673,647, filed on May 24, 2024.
(60) Provisional application No. 63/613,149, filed on Dec. 21, 2023.

(51) Int. Cl. H01L 25/18; H01L 21/56; H01L 23/00; H01L 23/48; H01L 23/498; H01L 23/528

(52) U.S. Cl. CPC H01L 25/18; H01L 21/56; H01L 23/481; H01L 23/49833; H01L 23/5283; H01L 24/16; H01L 24/32; H01L 24/73; H01L 2224/16225; H01L 2224/32225; H01L 2224/73204; H01L 2924/1815

(57) ABSTRACT

A package includes a die. The die includes: a substrate; electrical components at a front side of the substrate; an interconnect structure at the front side of the substrate and electrically coupled to the electrical components, where an uppermost conductive line of the interconnect structure is an aluminum line; and a via extending from the uppermost conductive line to a backside of the substrate. The package further includes: a molding material around the die; a first redistribution structure (RDS) under the die and the molding material; a second RDS over the die and the molding material, where each of the first RDS and the second RDS comprises dielectric layers and conductive features in the dielectric layers, where the via of the die is electrically coupled to the first RDS and the second RDS; and a second die over and electrically coupled to the second RDS.

### PRIORITY CLAIM AND CROSS-REFERENCE

This application is a continuation of U.S. patent application Ser. No. 18/673,647, filed on May 24, 2024 and entitled “Three-Dimensional Integrated Circuits and Methods Of Forming,” which claims the benefit of U.S. Provisional Application No. 63/613,149, filed on Dec. 21, 2023 and entitled “Specialty Technologies Chiplet with TSV-On-Top-Aluminum Interconnect to Back-Side and Front-Side Copper Post-Passivation Interconnects,” which applications are hereby incorporated by reference in their entireties.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size (e.g., shrinking the semiconductor process node towards the sub-20 nm node), which allows more components to be integrated into a given area. As the demand for miniaturization, higher speed and greater bandwidth, as well as lower power consumption and latency has grown recently, there has grown a need for smaller and more creative packaging techniques of semiconductor dies.

As semiconductor technologies further advance, stacked semiconductor devices, e.g., three-dimensional integrated circuits (3DICs), have emerged as an effective alternative to further reduce the physical size of a semiconductor device. In a stacked semiconductor device, active circuits such as logic, memory, processor circuits and the like are fabricated on different semiconductor wafers. Two or more semiconductor components may be installed on top of one another to further reduce the form factor of the semiconductor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a specialty technology semiconductor device, in accordance with an embodiment.

FIG. 2 illustrates a cross-sectional view of a specialty technology semiconductor device, in accordance with another embodiment.

FIGS. 3-8 illustrate cross-sectional views of a three-dimensional integrated circuit (3DIC) device at various stages of manufacturing, in accordance with an embodiment.

FIG. 9 illustrates a cross-sectional view of a semiconductor package, in accordance with an embodiment.

FIG. 10 illustrates a cross-sectional view of a semiconductor package, in accordance with another embodiment.

FIG. 11 illustrates a cross-sectional view of a semiconductor package, in accordance with yet an embodiment.

FIG. 12 illustrates a cross-sectional view of a silicon local interconnect (LSI) interposer, in accordance with an embodiment.

FIG. 13 illustrates a flow chart of a method of forming a semiconductor package, in accordance with an embodiment.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. Throughout the discussion herein, unless otherwise specified, the same or similar reference numeral in different figures refer to the same or similar components formed by the same or similar formation method using the same or similar material(s). In addition, in the discussion herein, unless otherwise specified, the term “conductive” refers to electrically conductive (e.g., instead of thermally conductive), and the term “conductive features” refer to electrically conductive features.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, a specialty technology device is vertically integrated with other semiconductor devices to form a 3DIC device. A molding material surrounds the specialty technology device. A backside redistribution structure (RDS) and a front side RDS are formed at a backside and a front side of the specialty technology device, respectively. One or more semiconductor devices are physically and electrically coupled to a first side of the front side RDS facing away from the specialty technology device. The specialty technology device includes a substrate, electrical components formed over the substrate, an interconnect structure over the electrical components, and vias that extend from a topmost conductive line (e.g., an aluminum line) of the interconnect structure to the backside of the specialty technology device. The vias provide vertical electrical connection between the front side RDS and the backside RDS. The disclosed via structure allows for a unified approach to integrate specialty technology devices with other semiconductor devices, regardless of the types or functionalities of the specialty technology devices. In some embodiments, the semiconductor devices and the specialty technology device in the 3DIC device are formed using different process nodes, which allows for flexibility in the choice of devices integrated in the 3DIC device, and allows for the 3DIC device to be formed inexpensively.

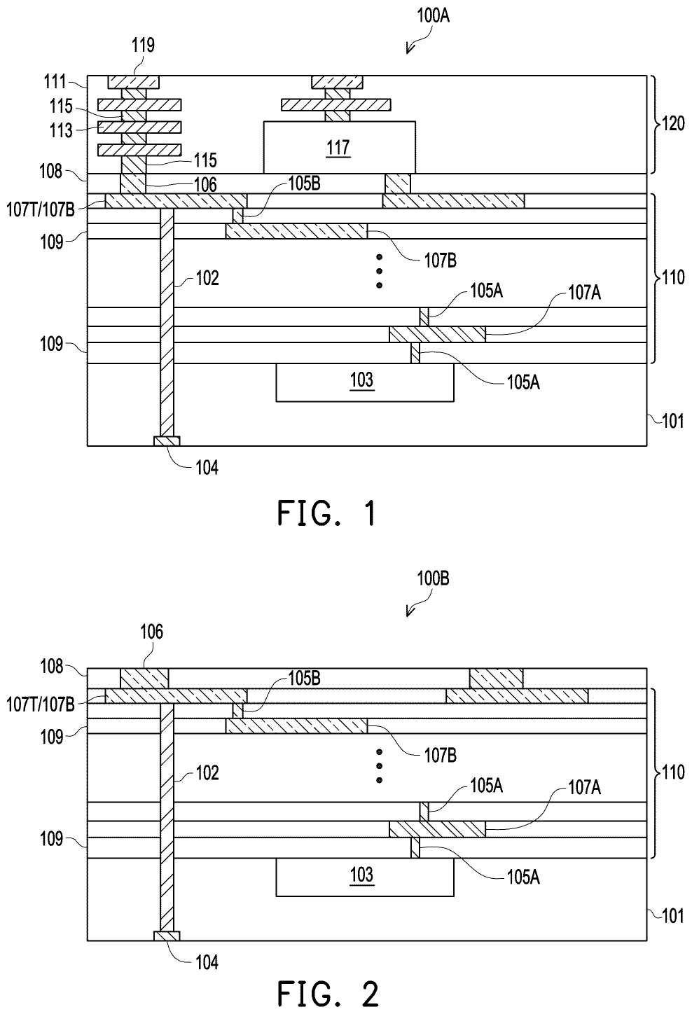

FIG. 1 illustrates a cross-sectional view of a specialty technology semiconductor device 100A (may also be referred to as a specialty technology device, or a specialty technology die), in accordance with an embodiment. In the discussion herein, specialty technology device may refer to semiconductor devices formed using non-CMOS technologies, such as gallium nitride (GaN) technology, Bipolar-CMOS-DMOS (BCD) technology, or the like. Specialty technologies may be used to form a wide variety of specialty technology devices, such as radio frequency devices, mixed signal devices, analog devices, passive devices (e.g., resistors, inductors, capacitors, or photo diode), micro-electromechanical system (MEMS) devices, embedded Flash (eFlash) devices, image sensors, or the like.

As illustrated in FIG. 1, the specialty technology device 100A includes a substrate 101, a device region 103, an interconnect structure 110, a passivation layer 108, and a post-processing interconnect (PPI) 120. In addition, the specialty technology device 100A includes vias 102 (may also be referred to as through-vias) that extend from a topmost conductive line 107T of the interconnect structure 110 to conductive bumps 104 at a backside of the specialty technology device 100A.

The substrate 101 may comprise, for example, bulk silicon, doped or undoped, or an active layer of a semiconductor-on-insulator (SOI) substrate. Generally, an SOI substrate comprises a layer of a semiconductor material, such as silicon, formed on an insulator layer. The insulator layer may be, for example, a buried oxide (BOX) layer or a silicon oxide layer. The insulator layer is provided on a substrate, such as a silicon or glass substrate. Alternatively, the substrate 101 may include another elementary semiconductor, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

Electrical components, such as transistors, capacitors, resistors, diodes, photo-diodes, fuses, and the like, are formed in the device region 103 at a front side of the substrate 101 (e.g., at an interface between the substrate 101 and the interconnect structure 110). The interconnect structure 110 is formed over the device region 103 and substrate 101. The interconnect structure 110 may include dielectric layers 109 (e.g., inter-layer dielectric (ILD) and/or inter-metal dielectric (IMD) layers) and conductive features (e.g., conductive lines 107 and vias 105) formed in the dielectric layers 109. The interconnect structure 110 electrically connects various electrical components in the device regions 103 to form functional circuits of the specialty technology device 100A. The functions provided by such circuits may include memory structures, processing structures, sensors, amplifiers, power distribution, power management, input/output (I/O) circuitry, or the like. One of ordinary skill in the art will appreciate that the above examples are provided for illustrative purposes only and are not meant to limit the present application in any manner. Other circuitry may be used as appropriate for a given application.

The dielectric layers 109 may be formed of low-K dielectric materials having dielectric constant values (also referred to as K values), for example, lower than about 4.0 or even 2.0. In some embodiments, the dielectric layers 109 are formed of, for example, phosphosilicate glass (PSG), borophosphosilicate glass (BPSG), fluorosilicate glass (FSG), SiOₓC_{y}, Spin-On-Glass, Spin-On-Polymers, silicon carbon material, compounds thereof, composites thereof, combinations thereof, or the like, using any suitable method, such as spinning, chemical vapor deposition (CVD), and plasma-enhanced CVD (PECVD).

The conductive lines 107 (e.g., 107A and 107B) and the vias 105 (e.g., 105A and 105B) are formed in the dielectric layers 109 using a suitable conductive material, such as copper, aluminum, tungsten, combinations thereof, or the like, using any suitable method. In some embodiments, conductive features in lower portions of the interconnect structure 110 (e.g., proximate to the substrate 101), such as conductive lines 107A and vias 105A, are formed of a conductive material (e.g., copper) different from the conductive material (e.g., aluminum) of conductive features (e.g., conductive lines 107B and vias 105B) in upper portions of the interconnect structure 110 (e.g., distal from the substrate 101). The conductive lines 107A and 107B may be collectively referred to as conductive lines 107, and the vias 105A and 105B may be collectively referred to as vias 105. In other embodiments, all of the conductive features (e.g., conductive lines 107, vias 105) of the interconnect structure 110 are formed of the same material (e.g., aluminum). Aluminum is a less expensive material than copper, and therefore, using aluminum for some, or all, of the conductive features in the interconnect structure 110 reduces production cost. In some embodiments, despite the wide variety of functionalities of specialty technology devices and the wide variety of the specialty technologies used to form the specialty technology devices, the conductive features (e.g., conductive lines 107B and vias 105B) in the upper portions of the interconnect structure 110 are formed of aluminum. In particular, at least the topmost conductive lines 107T (e.g., the conductive lines 107B furthest from the substrate 101) are formed of aluminum. Notably, each of the vias 102 is formed to extend from a topmost conductive line 107T of the interconnect structure 110 to a respective conductive bump 104 (may also be referred to as connector) at a backside of the substrate 101. By designing the vias 102 to be in contact (e.g., in physical contact) with the topmost conductive line 107T of the interconnect structure 110, a unified via design can be used for integrating different types of specialty technology devices in the 3DIC device 200.

The vias 102 may be formed by forming openings that extend from the backside of the substrate 101 to the topmost conductive lines 107, then filling the openings with a conductive material, such as copper or aluminum. In some embodiments, using copper as the material for the vias 102 provides improved electromigration robustness. The conductive bumps 104 may be, e.g., ball grid array (BGA) balls, microbumps (μbumps), controlled collapse chip connection (C4) bumps, copper pillars, and the like, and may be formed by any suitable formation method. In some embodiments, the thickness (e.g., diameter) of the via 102 is between about 1 μm and about 50 μm. A pitch between adjacent vias 102 may be between about 20 μm and about 100 μm.

Next, input/output (I/O) features and passivation features may be formed over the interconnect structure 110. For example, contact pads 106 (e.g., aluminum pads) may be formed over the interconnect structure 110 and may be electrically connected to the device region 103 through the various conductive features in the interconnect structure 110. The contact pads 106 may comprise a conductive material such as aluminum, copper, and the like. Furthermore, the passivation layer 108 may be formed over the interconnect structure 110 and the contact pads 106. In some embodiments, the passivation layer 108 is formed of a polymer material, such as polyimide. In some embodiments, the passivation layer 108 is formed of non-organic materials such as silicon oxide, un-doped silicate glass, silicon oxynitride, and the like. Other suitable passivation materials may also be used. Portions of the passivation layer 108 may cover edge portions of contact pads 106.

Next, the PPI 120 is formed on the passivation layer 108 and is electrically coupled to the interconnect structure 110, e.g., through the contact pads 106. In some embodiments, the PPI 120 comprises dielectric layers 111 and conductive features (e.g., conductive lines 113 and vias 115) formed in the dielectric layers 111. The conductive lines 113 and the vias 115 may be formed of a suitable conductive material, such as copper. The PPI 120 may be formed using a same or similar formation methods as the interconnect structure 110, thus details are not discussed here. In some embodiments, the thickness (e.g., line width) of the conductive lines 113 (e.g. copper lines) of the PPI 120 is between about 1 μm and about 30 μm. The number of dielectric layers 111 in the PPI 120 may be between, e.g., about 1 and about 20. A total thickness of the specialty technology device 100A, measured along the vertical direction of FIG. 1, may be between, e.g., 5 μm and about 1200 μm. A thickness of the PPI 120 may be between about 1 μm and about 30 μm. The PPI 120 and the interconnect structure 110 are disposed at the front side of the specialty technology device 100A. The conductive bumps 104 are disposed at the backside of the specialty technology device 100A.

In the example of FIG. 1, besides conductive lines and vias, the PPI 120 includes electrical components 117 formed in the dielectric layers 111. Example of the electrical components 117 include capacitors, inductors, resistors, or the like. For example, metal-insulator-metal (MIM) capacitors may be formed by forming metal patterns (e.g., copper patterns) and high-K dielectric material between the metal patterns in the PPI 120. As another example, a coil may be formed by forming copper patterns in one or more dielectric layers 111. The electrical components 117 may be connected to electrical components in the device region 103 by the interconnect structure 110 to form functional circuits of the specialty technology device 100A. For example, the specialty technology device 100A may be a power management integrated circuit (IC), and the capacitors and/or the inductors of the electrical components 117 may function as the switching capacitors and/or the switching regulators of the power management IC. In some embodiments, the electrical components 117 are omitted in the PPI 120.

Still referring to FIG. 1, conductive bumps 119 (also referred to as connectors) are formed over and electrically coupled to the PPI 120. The conductive bumps 119, together with conductive bumps 104, provide electrical connection between the specialty technology device 100A and another electrical device. In some embodiments, the conductive bumps 119 are solder balls, such as BGA balls, microbumps, C4 bumps, and the like. The conductive bumps 119 may comprise a Sn—Ag alloy, a Sn—Cu alloy, a Sn—Ag—Cu alloy, or the like, and may be lead-free solder caps or lead containing solder caps.

The various features of the specialty technology device 100A may be formed by any suitable method and are not described in further detail herein. Furthermore, the general features and configuration of the specialty technology device 100A described above are but one example embodiment, and the specialty technology device 100A may include any combination of any number of the above features as well as other features.

FIG. 2 illustrates a cross-sectional view of a specialty technology semiconductor device 100B (may also be referred to as a specialty technology device, or a specialty technology die), in accordance with another embodiment. The specialty technology device 100B is similar to the specialty technology semiconductor device 100A, but without the PPI 120. In discussion hereinafter, the term “specialty technology device 100” may be used to refer to either the specialty technology device 100A or the specialty technology device 100B.

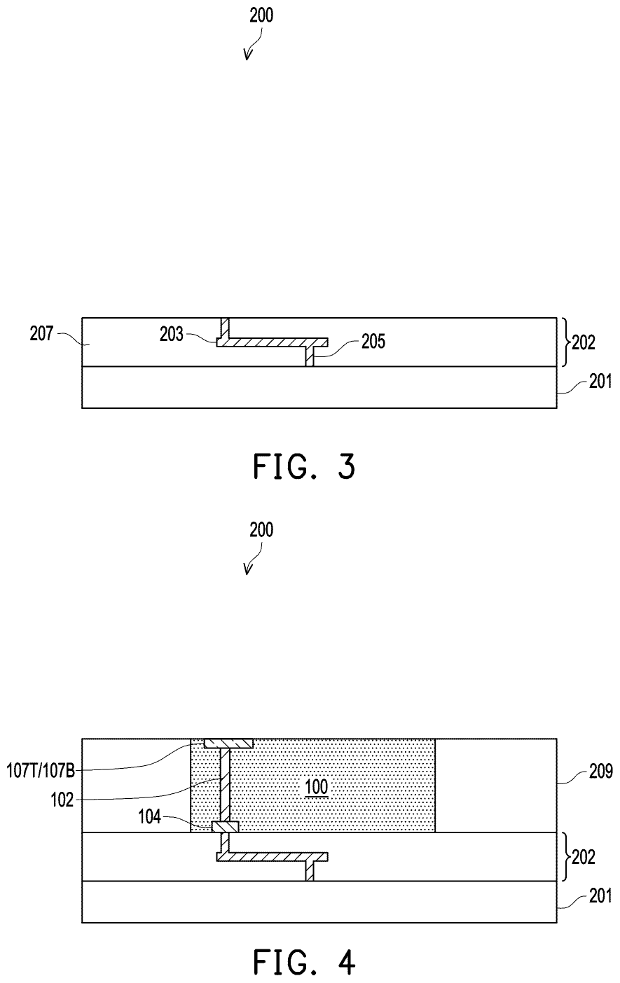

FIGS. 3-8 illustrate cross-sectional views of a three-dimensional integrated circuit (3DIC) device 200 at various stages of manufacturing, in accordance with an embodiment. The 3DIC device 200 may also be referred to as a semiconductor package.

In FIG. 3, a redistribution structure (RDS) 202 is formed over a carrier 201 (may also be referred to as a carrier substrate 201). The carrier 201 may be a glass carrier substrate, a ceramic carrier substrate, or the like. The carrier 201 may be a wafer, such that multiple 3IDC devices 200 can be formed on the carrier 201 simultaneously.

In some embodiments, the RDS 202 (may also be referred to as a backside RDS 202) comprises conductive features such as one or more layers of conductive lines 203 and vias 205 formed in one or more dielectric layers 207. In some embodiments, the dielectric layer 207 is formed of a polymer, such as polybenzoxazole (PBO), polyimide, benzocyclobutene (BCB), or the like. In other embodiments, the dielectric layer 207 is formed of a nitride such as silicon nitride; an oxide such as silicon oxide, phosphosilicate glass (PSG), borosilicate glass (BSG), or boron-doped phosphosilicate glass (BPSG); or the like. The one or more dielectric layers 207 may be formed by any acceptable deposition process, such as spin coating, chemical vapor deposition (CVD), laminating, the like, or a combination thereof.

In some embodiments, the conductive features of the RDS 202 comprise conductive lines 203 and via 205 formed of a suitable conductive material such as copper, titanium, tungsten, aluminum, or the like. The formation process of the RDS 202 may include: forming the dielectric layer 207; forming openings in the dielectric layers 207 to expose underlying conductive features; forming a seed layer over the dielectric layer 207 and in the openings; forming a patterned photoresist with a designed pattern (e.g. openings) over the seed layer; plating (e.g., electroplating or electroless plating) the conductive material in the designed pattern and over the seed layer; and removing the photoresist and portions of seed layer on which the conductive material is not formed. The above process can be repeated until a target number of dielectric layers 207 and conductive features are formed in the RDS 202.

In some embodiments, a release layer (not illustrated) is formed on the carrier 201 before the RDS 202 is formed. The release layer may be formed of a polymer-based material, which may be removed along with the carrier substrate 201 from the overlying structures that will be formed in subsequent steps. In some embodiments, the release layer is an epoxy-based thermal-release material, which loses its adhesive property when heated, such as a light-to-heat-conversion (LTHC) release coating. In other embodiments, the release layer may be an ultra-violet (UV) glue, which loses its adhesive property when exposed to UV lights. The release layer may be dispensed as a liquid and cured, or may be a laminate film laminated onto the carrier substrate 201, as examples. The top surface of the release layer may be leveled and may have a high degree of coplanarity.

Next, in FIG. 4, a specialty technology device 100 is attached (e.g., bonded) to an upper surface of the RDS 202, and a molding material 209 is formed over the upper surface of the RDS 202 around the specialty technology device 100. The specialty technology device 100 may be the specialty technology device 100A in FIG. 1 or the specialty technology device 100B in FIG. 2, as examples. For simplicity, details of the specialty technology device 100 may not be illustrated in FIG. 4 and subsequent figures, although some features, such as the via 102, the topmost conductive line 107T, and the conductive bumps 104 are illustrated, with the understanding that other features of the specialty technology device 100 not illustrated in FIGS. 4-11 are formed as illustrated in FIG. 1 or FIG. 2.

In some embodiments, the conductive bumps 104 at the backside of the specialty technology device 100 is bonded to conductive features exposed at the upper surface of the RDS 202. The conductive bumps 104 may be bonded using a solder material, or may be bonded using a hybrid bonding technique where dielectric-to-dielectric bonding and metal-to-metal bonding are used to bond the specialty technology device 100 to the RDS 202 without using an adhesive material or solder material. As illustrated in FIG. 4, the vias 102 of the specialty technology device 100 are electrically coupled to the conductive features of the RDS 202, e.g., through the conductive bumps 104.

Next, the molding material 209 is formed on the RDS 202 around the specialty technology device 100. In some embodiments, the molding material 209 comprises an epoxy, an organic polymer, a polymer with or without a silica-based or glass filler added, or other materials. In some embodiments, the molding material 209 comprises a liquid molding compound (LMC) that is a gel type liquid when applied. The molding material 209 may also comprise a liquid or solid when applied. Alternatively, the molding material 209 may comprise other insulating and/or encapsulating materials. The molding material 209 is applied using a wafer level molding process in some embodiments. The molding material 209 may be molded using, for example, compressive molding, transfer molding, or other methods.

Next, the molding material 209 is cured using a curing process, in some embodiments. The curing process may comprise heating the molding material 209 to a predetermined temperature for a predetermined period of time, using an anneal process or other heating process. The curing process may also comprise an ultra-violet (UV) light exposure process, an infrared (IR) energy exposure process, combinations thereof, or a combination thereof with a heating process. Alternatively, the molding material 209 may be cured using other methods. In some embodiments, a curing process is not included.

Next, a planarization process, such as chemical mechanical planarization (CMP), is performed to remove excess portions of the molding material 209 and to achieve a coplanar upper surface between the specialty technology device 100 and the molding material 209.

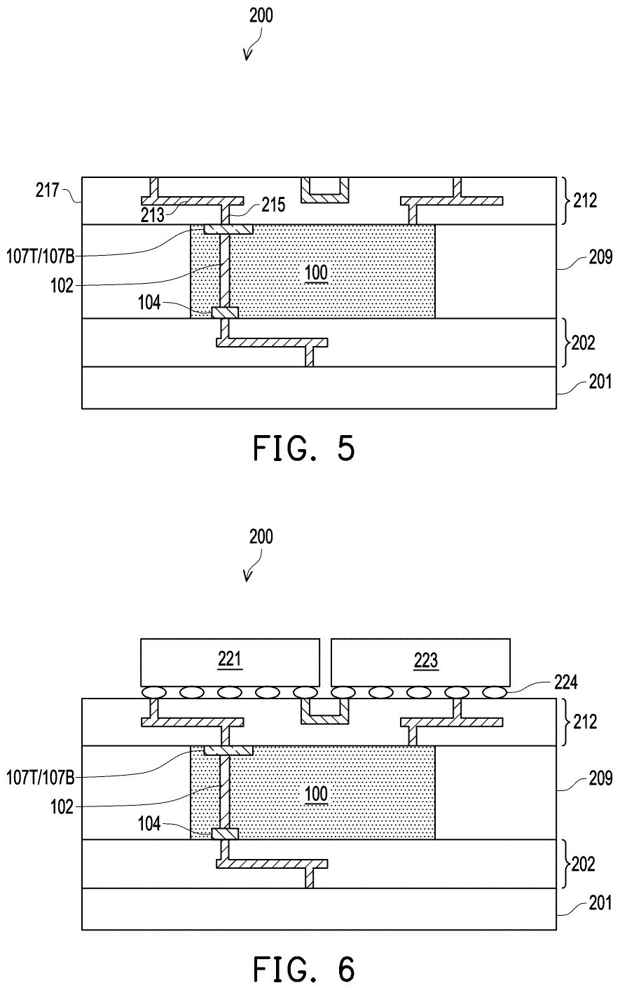

Next, in FIG. 5, an RDS 212 (also referred to as a front side RDS 212) is formed on the front side of the specialty technology device 100 and the molding material 209. The RDS 212 includes dielectric layer 217 and conductive features (e.g., conductive lines 213 and vias 215) formed in the dielectric layers 217. The RDS 212 may be formed using the same or similar formation method as the RDS 202, thus details are not repeated.

The conductive features of the RDS 212 are electrically coupled to the specialty technology device 100. As illustrated in FIG. 5, the vias 102 of the specialty technology device 100 are electrically coupled to the conductive features of the RDS 212, e.g., through the topmost conductive lines 107T and the conductive bumps 119 (see FIG. 1), or through the topmost conductive lines 107T and the contact pads 106 (see FIG. 2). Therefore, the vias 102 electrically couples the RDS 212 with the RDS 202.

Next, in FIG. 6, semiconductor devices 221 and 223 (e.g., semiconductor dies) are attached to the upper surface of the RDS 212. For example, conductive connectors 224 of the semiconductor devices 221 and 223 are bonded to conductive features of the RDS 212, e.g., using a solder material. The semiconductor device 221 and 223 are electrically coupled to the specialty technology device 100 through the RDS 212. In addition, the semiconductor device 221 and 223 are electrically coupled to each other by conductive features of the RDS 212.

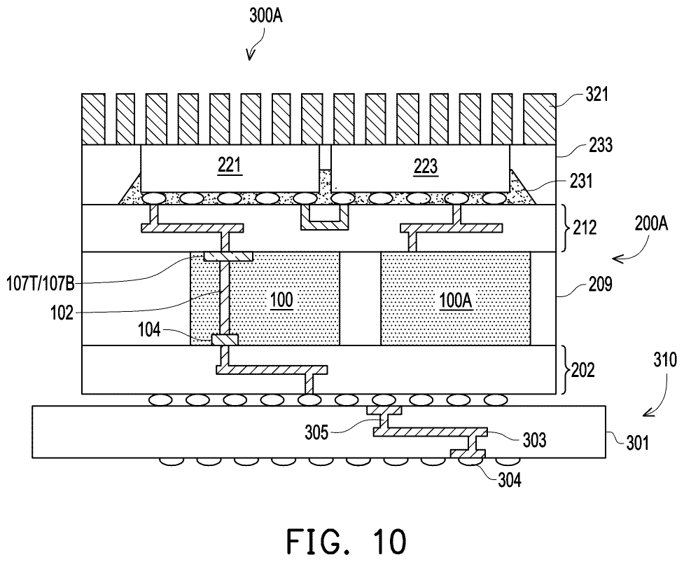

In some embodiments, semiconductor devices (e.g., 221, 223, 100) of different functionalities are integrated together (e.g., as illustrated in FIG. 6) to form the 3DIC device 200. For example, the semiconductor device 221 may be a processor (e.g., a micro-controller, a digital signal processor, or the like), the semiconductor device 223 may be a memory device (e.g., a DRAM device) that includes memory cells for storing digital information, and the specialty technology device 100 may be a power management IC (PMIC) device that performs, e.g., DC-DC power conversion and provides regulated power supplies to the semiconductor devices 221 and 223. The PMCI device (e.g., 100) may include inductors and/or capacitors (see, e.g., 117 in FIG. 1) formed in the PPI 120 of the PMIC device. As another example, the semiconductor device 223 may be a memory device that includes memory cells but does not include the control circuit (e.g., for controlling reading/writing of the memory cells) of the memory cells. The control circuit of the memory cells are implemented in the specialty technology device 100, and therefore, the semiconductor device 223 and the specialty technology device 100 together provide the full functionality of a memory IC device. As yet another example, two specialty technology devices, which includes a specialty technology device 100 (a PMIC device) and a specialty technology device 100A (a memory control circuit), are embedded in the molding material 209 to form a 3DIC device, as illustrated by the 3DIC device 200A in FIG. 10. The number of semiconductor devices in the 3DIC device 200 and the functionalities of the semiconductor devices discussed above are non-limiting examples, as one of ordinary skill readily appreciates. The number of semiconductor devices in the 3DIC device 200 may be any suitable number, and the semiconductor devices in the 3DIC device 200 may perform any suitable functionalities.

In some embodiments, the semiconductor devices 221 and 223 are formed by more advanced process node(s) than the specialty technology device 100. Process node, also referred to process technology or technology node, is a term of art that refers to the semiconductor manufacturing technology used for fabricating semiconductor devices. A process node is typically characterized by the critical dimension (CD) of the process node. The CD of a process node is also a term of art that is used to indicate the smallest feature size achieved by the process node, which is typically measured as the minimum line width that can be produced by the process node. Therefore, the CD of a process node may be used interchangeably with the minimum line width of the process node, in some embodiments. Currently, advanced process nodes for semiconductor manufacturing include 7 nm node, 3 nm node, and the like. Examples of older process nodes include 65 nm node, 90 nm node, 110 nm node, 800 nm node, 3 μm node, 10 μm node, 50 μm node, and the like.

Advantages may be achieved by integrating semiconductor devices formed by different process nodes into the 3DIC 200. For example, the semiconductor devices 221 and 223 may be high performance devices (e.g., high performance processor, or high-bandwidth high-capacity memory devices) that integrates large numbers (e.g., millions or more) of transistors. Using advanced process nodes for the semiconductor devices 221 and 223 allows large number of transistors to be integrated into a small semiconductor die area, thus improving integration density and reducing production cost for the semiconductor devices. Additional advantages may include lower power consumption. The specialty technology device 100, due to its functionality or design/performance requirements, may be well suited for an older process node. For example, the specialty technology device 100 may require integration of capacitors, and the thicker line width of the older process nodes may be more efficient to achieve large capacitances for the capacitors. As another example, the specialty technology device 100 may have a different electrical rating or performance requirements (e.g., a high-voltage device), and those performance requirements may be easier and less expensive to achieve using older process nodes and/or a non-CMOS technology. In some embodiments, the semiconductor devices 221 and 223 are formed by CMOS technology, while the specialty technology device 100 is formed by a non-CMOS technology, and the CD of the non-CMOS technology is larger than that of the CMOS technology. The disclosed embodiments, by allowing semiconductor devices formed by different process nodes to be integrated together, allows 3DIC devices with a wide variety of functionalities to be formed inexpensively.

Note that the vias 102 provide vertical electrical connection between the front side RDS 212 and the backside RDS 202, which allows power signals (e.g., power supplies, or electrical ground) and data signals to be routed easily between the front side RDS 212 and the backside RDS 202. Without the vias 102, vertical routing of the power signals and data signals may be difficult, and as a result of this difficulty, specialty technology devices without the vias 102 are typically coupled to a package substrate or a printed circuit board (PCB) at a same vertical level (e.g., side-by-side) with other semiconductor devices. In other words, vertical stacking of specialty technology devices with other semiconductor devices (e.g., 221, 223) may be difficult without the vias 102.

To further illustrate the advantage of the vias 102, consider a reference 3DIC device where a specialty technology device without the vias 102 is integrated with a larger number (e.g., 4 or more) of semiconductor devices 221/223 in a similar configuration as FIG. 6. In the reference 3DIC device, the large number of semiconductor devices 221/223 are typically aligned along a single row, such that there are enough spaces around the semiconductor devices 221/223 to form vias that extend through the molding material 209 to electrically couple the RDS 202 with the RDS 212. In contrast, the specialty technology device 100 with vias 102 provides the vertical electrical connection between the RDS 202 and 212, and allows the semiconductor devices 221/223 to be arranged in a matrix format, e.g., arranged in a 2-by-2 configuration in a top view for a total of four semiconductor devices 221/223. This allows more compact integration of the semiconductor devices 221/223 (thus a smaller area for the 3DIC device), and more flexibility in the placement of the semiconductor devices 221/223 in the 3DIC device.

In some embodiments, the specialty technology device 100 is formed using a first process node, and the semiconductor devices 221 and 223 are formed using a second process node, where the CD (or the minimum line width) of the first process node is larger than the CD (or the minimum line width) of the second process node. In addition, the RDS 202 and 212 are formed using a third process node, where the CD (or the minimum line width) of the third process node is larger than the CD of the first process node. Since the RDS 202 and the RDS 212 have less stringent requirement for the line width due to less area restriction, using an older process node (which has larger CD or lager minimum line width) allows the RDS 202 and the RDS 212 to be formed inexpensively.

Variations to the disclosed embodiments are possible and are fully intended to be included within the scope of the present disclosure. In the above example, the specialty technology device 100 is formed using an older process node than the semiconductor devices 221 and 223. This is merely a non-limiting example. The specialty technology device 100 may be formed using any suitable process node, including the advanced process nodes. The semiconductor devices 221 and 223 may be formed of different process nodes that are more advanced (e.g., having smaller CDs) than that of the specialty technology device 100. The number of specialty technology devices and the number of the semiconductor devices integrated in the 3DIC device may be any suitable number, as one of ordinary skill readily appreciates.

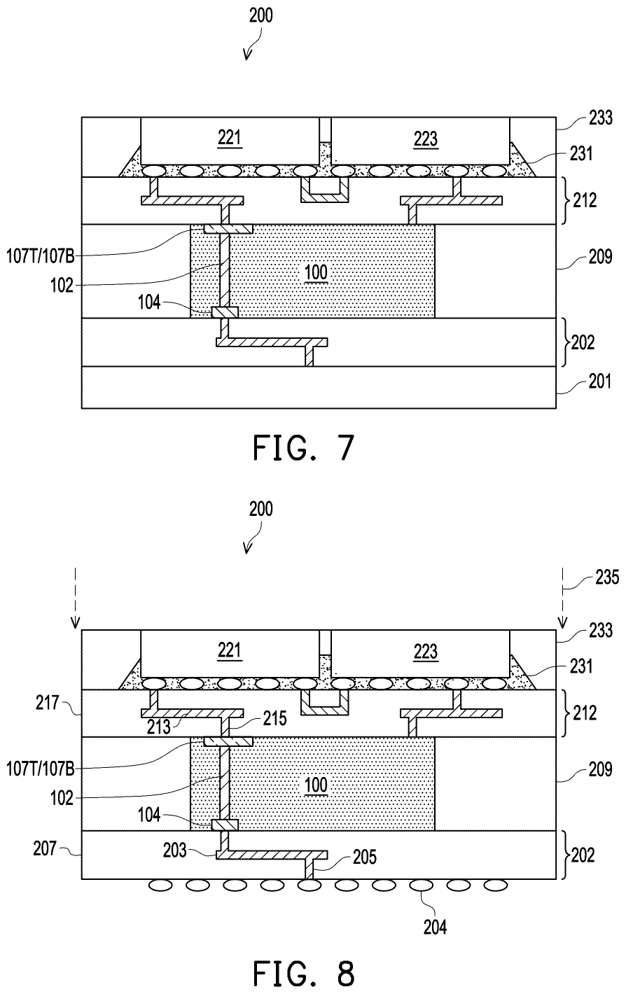

Next, in FIG. 7, an underfill material 231 is deposited to fill the gap between the semiconductor devices 221 and 223 and the RDS 212. The underfill material 231 may extend along sidewalls of the semiconductor devices 221 and 223. Examples of the underfill material 231 include, but are not limited to, polymers and other suitable non-conductive materials. The underfill material 231 may be dispensed in the gap between the semiconductor devices 221 and 223 and the RDS 212 using, e.g., a needle or a jetting dispenser. A curing process may be performed to cure the underfill material 231.

Next, a molding material 233 is formed on the RDS 212 around the semiconductor devices 221 and 223. The molding material 233 may be the same or similar as the molding material 209, and may be formed using a same or similar formation method. After the molding material 233 is formed, a planarization process, such as CMP, may be performed to achieve a coplanar upper surface between the molding material 233 and the semiconductor devices 221 and 223.

Next, in FIG. 8, the carrier 201 is removed, e.g., by a carrier de-bonding process. In accordance with some embodiments, the de-bonding includes projecting a light such as a laser light or an UV light on the release layer so that the release layer decomposes under the heat of the light and the carrier substrate 201 can be removed. The remaining structure is then flipped over and placed on a tape, which holds the remaining structure in place. Next, conductive bumps 204 are formed at an exterior surface of the RDS 202 distal from the specialty technology device 100. The conductive bumps 204 are electrically coupled to the conductive features of the RDS 202. The conductive bumps 204 may be formed by the same or similar formation method as the conductive bumps 104 or 119, thus details are not repeated. In some embodiments, multiple 3DIC devices 200 are formed on the carrier 201 simultaneously, and therefore, a dicing process is performed next along scribe line regions (indicated by dashed lines 235) between adjacent 3DIC devices 200 to form individual (e.g., separate) 3DIC devices 200.

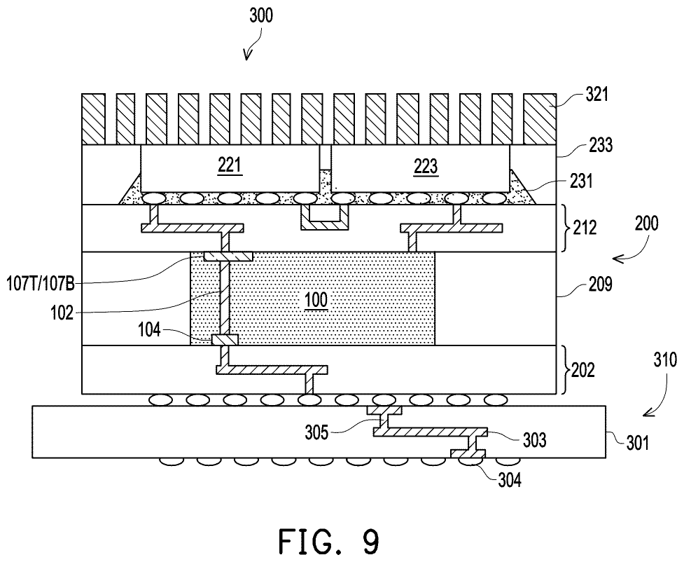

F FIG. 9 illustrates a cross-sectional view of a semiconductor package 300, in accordance with an embodiment. The semiconductor package 300 is formed by attaching the 3DIC device 200 to a work piece 310, which may be, e.g., a package substrate or a printed circuit board (PCB). The work piece 310 may include a substrate 301 (e.g., a dielectric core comprising one or more layers of dielectric material) and conductive features (e.g., conductive lines 303 and vias 305) that route electrical signals, e.g., from a first side of the substrate 301 to an opposing second side of the substrate 301. In the example of FIG. 9, the 3DIC device 200 is bonded to the first side of the substrate 301, e.g., by a solder material. Conductive bumps 304 are formed at the second opposing side of the substrate 301. The conductive bumps 304 may be the same as or similar to the conductive bumps 204, thus details are not repeated. In FIG. 9, a heat sink 321, which is optional, is attached to the molding material 233 and the semiconductor devices 221 and 223.

FIG. 10 illustrates a cross-sectional view of a semiconductor package 300A, in accordance with another embodiment. The semiconductor package 300A is similar to the semiconductor package 300, but with a 3DIC device 200A attached to the work piece 310. The 3DIC device 200A is similar to the 3DIC device 200, but with two specialty technology devices 100 and 100A embedded in the molding material 209. The specialty technology device 100 has vias 102 that provide vertical electrical connection, and may be, e.g., a PMIC device. The specialty technology device 100A may or may not have the vias 102, and may be, e.g., a control circuit for the semiconductor device 223 (e.g., a memory device).

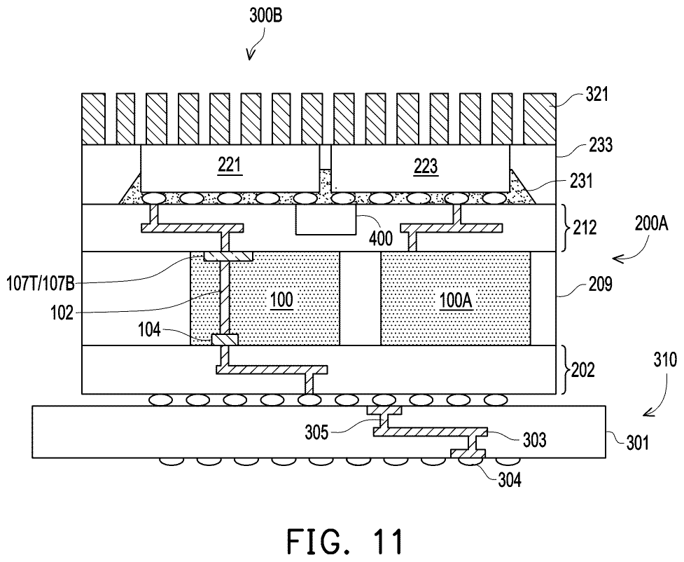

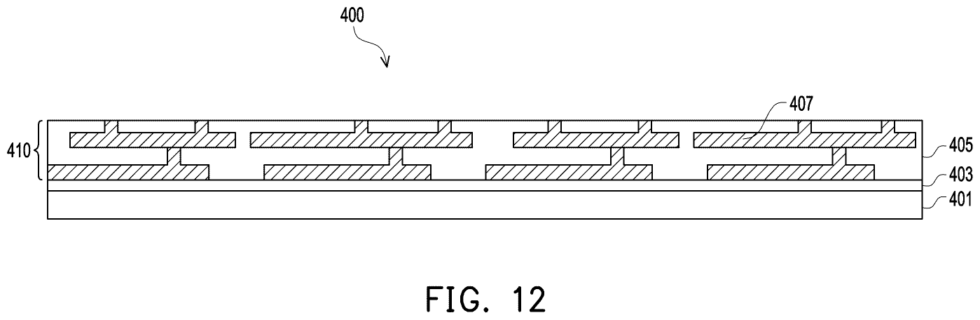

FIG. 11 illustrates a cross-sectional view of a semiconductor package 300B, in accordance with yet an embodiment. The semiconductor package 300B is similar to the semiconductor package 300A, but with a local silicon interconnect (LSI) interposer 400 embedded in the RDS 212 to provide electrical connection between the semiconductor devices 221 and 223. Details of the LSI interposer 400 are illustrated in FIG. 12.

FIG. 12 illustrates a cross-sectional view of the LSI interposer 400. As illustrated in FIG. 12, the LSI interposer 400 includes a substrate 401 (e.g., a glass substrate, a ceramic substrate, a dielectric substrate, a semiconductor substrate (e.g., a bulk silicon substrate), or the like), a dielectric layer 403 (e.g., silicon oxide) over the substrate 401, and an RDS 410 over the dielectric layer 403. The RDS 410 includes one or more dielectric layers 405 (e.g., silicon oxide) and conductive features 407 (e.g., conductive lines and vias) formed in the one or more dielectric layers 405. In some embodiments, the LSI interposer 400 is formed using the same back-end-of-line (BEOL) processing for forming the interconnect structure of the semiconductor device 221 (or 223), and therefore, the critical dimension (e.g., the minimum line width) of the LSI interposer 400 is the same as that of the semiconductor device 221 (or 223) to allow for high-density routing. In other words, the process node of the LSI interposer 400 may be the same as that of the semiconductor device 221 (or 223). Since the RDS 212 is formed using an older process node, the critical dimension of the RDS 212 is larger than that of the LSI interposer 400.

Referring back to FIG. 11, the dielectric layers of the RDS 212 may be formed of an organic material (e.g., a polymer material such as polyimide). The LSI interposer 400, which is pre-formed, is embedded in the organic material of the RDS 212.

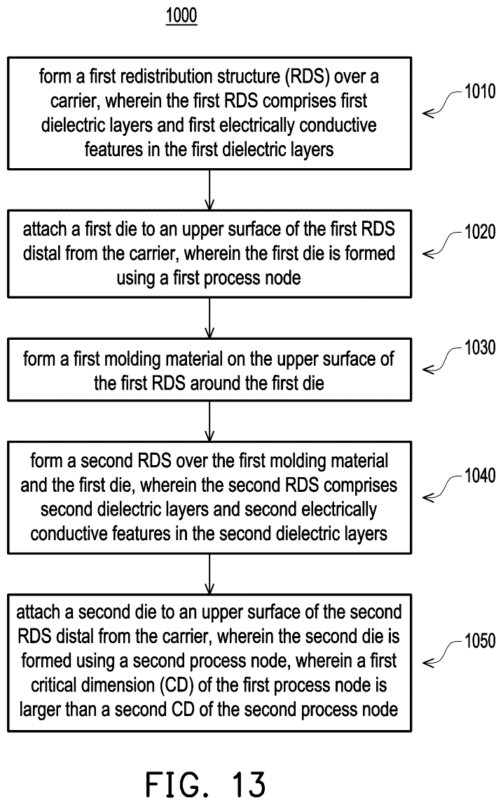

FIG. 13 illustrates a flow chart of a method 1000 of forming a semiconductor package, in accordance with an embodiment. It should be understood that the embodiment method shown in FIG. 13 is merely an example of many possible embodiment methods. One of ordinary skill in the art would recognize many variations, alternatives, and modifications. For example, various steps as illustrated in FIG. 13 may be added, removed, replaced, rearranged, or repeated.

Referring to FIG. 13, at block 1010, a first redistribution structure (RDS) is formed over a carrier, wherein the first RDS comprises first dielectric layers and first electrically conductive features in the first dielectric layers. At block 1020, a first die is attached to an upper surface of the first RDS distal from the carrier, wherein the first die is formed using a first process node. At block 1030, a first molding material is formed on the upper surface of the first RDS around the first die. At block 1040, a second RDS is formed over the first molding material and the first die, wherein the second RDS comprises second dielectric layers and second electrically conductive features in the second dielectric layers. At block 1050, a second die is attached to an upper surface of the second RDS distal from the carrier, wherein the second die is formed using a second process node, wherein a first critical dimension (CD) of the first process node is larger than a second CD of the second process node.

Embodiments of the device and method in the current disclosure have many advantages. For example, by forming the vias 102 to extend from the topmost conductive line 107T (e.g., an aluminum line) of the interconnect structure 110 to the backside of the specialty technology device, a unified design methodology can be applied for vertically integrating specialty technology devices in a 3DIC device, regardless of the types or functionalities of the specialty technology devices. The disclosed 3DIC devices allows devices formed using different processing nodes to be integrated together, thus reducing the production cost and allows flexibility in choosing the process nodes for the different devices integrated in the 3DIC device. The vertical routing provided by the vias 102 allows flexibility in the placement of the semiconductor devices in the 3DIC device, which reduces the foot print of the 3DIC device and increase integration density.

In accordance with an embodiment, a package includes: a first redistribution structure (RDS) comprising one or more dielectric layers and electrically conductive features in the one or more dielectric layers; and a first die over and electrically coupled to a first side of the first RDS, wherein the first die comprises: a substrate; first electrical components over the substrate; an interconnect structure over the substrate at a front side of the first die, wherein the interconnect structure is over and electrically coupled to the first electrical components, wherein a topmost conductive line of the interconnect structure distal from the substrate comprises aluminum; a first conductive bump at a backside of the first die, wherein the first conductive bump is bonded to an electrically conductive feature of the first RDS; and a via extending from the topmost conductive line of the interconnect structure to the first conductive bump. The package further includes: a first molding material over the first side of the first RDS around the first die; a second RDS over the first molding material and the first die, wherein the second RDS is electrically coupled to the first die and the via; and a second die over and electrically coupled to the second RDS. In an embodiment, a first critical dimension (CD) of the first die is larger than a second CD of the second die. In an embodiment, a third CD of the first RDS is larger than the first CD of the first die. In an embodiment, the third CD of the first RDS is equal to a fourth CD of the second RDS. In an embodiment, the first die further comprises second electrical components embedded in the interconnect structure, wherein the interconnect structure is configured to connect the first electrical components and the second electrical components to form functional circuits of the first die. In an embodiment, the first electrical components comprise a transistor, wherein the second electrical components comprise a capacitor, an inductor, or a resistor. In an embodiment, the package further comprises: an underfill material between the second die and the second RDS; and a second molding material over the second RDS around the second die. In an embodiment, the package further comprises a heat sink attached to a first side of the second molding material distal from the second RDS. In an embodiment, the package further comprises a package substrate, wherein a second side of the first RDS opposing the first side of the first RDS is bonded to the package substrate. In an embodiment, the second die is a memory die comprising memory cells, wherein the first die comprises a control circuit for the memory die.

In accordance with an embodiment, a package includes a first die. The first die comprises: a substrate; electrical components at a front side of the substrate; an interconnect structure at the front side of the substrate and electrically coupled to the electrical components, wherein an uppermost conductive line of the interconnect structure distal from the substrate is an aluminum line; and a via extending from the uppermost conductive line of the interconnect structure to a backside of the substrate. The package further includes: a first molding material around the first die; a first redistribution structure (RDS) under the first die and the first molding material, wherein the first RDS comprises first dielectric layers and first conductive features in the first dielectric layers; a second RDS over the first die and the first molding material, wherein the second RDS comprises second dielectric layers and second conductive features in the second dielectric layers, wherein the via of the first die is electrically coupled to the first RDS and the second RDS; and a second die over and electrically coupled to the second RDS. In an embodiment, a minimum line width of the first die is larger than a minimum line width of the second die. In an embodiment, a minimum line width of the first RDS is larger than the minimum line width of the first die. In an embodiment, the package further comprises: a third die over and electrically coupled to the second RDS; and a local silicon interconnect (LSI) interposer embedded in the second RDS, wherein the LSI interposer comprises another substrate and a third RDS over the another substrate, wherein the second die is electrically coupled to the third die by the LSI interposer. In an embodiment, a lowermost conductive line of the interconnect structure proximate to the substrate is a copper line. In an embodiment, the first die further comprises a post-processing interconnect (PPI) over and electrically coupled to the interconnect structure, wherein the PPI comprises: third dielectric layers over the interconnect structure; third conductive features in the third dielectric layers; and conductive bumps at a first side of the PPI distal from the interconnect structure, wherein the conductive bumps are bonded to the second RDS.

In accordance with an embodiment, a method of forming a package includes: forming a first redistribution structure (RDS) over a carrier, wherein the first RDS comprises first dielectric layers and first electrically conductive features in the first dielectric layers; attaching a first die to an upper surface of the first RDS distal from the carrier, wherein the first die is formed using a first process node; forming a first molding material on the upper surface of the first RDS around the first die; forming a second RDS over the first molding material and the first die, wherein the second RDS comprises second dielectric layers and second electrically conductive features in the second dielectric layers; and attaching a second die to an upper surface of the second RDS distal from the carrier, wherein the second die is formed using a second process node, wherein a first critical dimension (CD) of the first process node is larger than a second CD of the second process node. In an embodiment, the first RDS and the second RDS are formed using a third process node, wherein a third CD of the third process node is larger than the first CD. In an embodiment, the first die is formed to include: a substrate; electrical components over the substrate; an interconnect structure at a front side of the substrate, wherein the interconnect structure is over and electrically coupled to the electrical components, wherein a topmost conductive line of the interconnect structure distal from the substrate is formed of aluminum; a conductive bump at a backside of the substrate; and a via extending from the topmost conductive line of the interconnect structure to the conductive bump, wherein the via of the first die is electrically coupled to the first RDS and the second RDS. In an embodiment, the method further includes: filling a gap between the second die and the second RDS with an underfill material; and after the filling, forming a second molding material over the second RDS around the second die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package comprising:
a first redistribution structure (RDS) comprising first dielectric layers and first electrically conductive features embedded in the first dielectric layers;
a first die attached to a first side of the first RDS, wherein the first die comprises:
a substrate;
a device region at a front side of the substrate;
an interconnect structure over and electrically coupled to the device region, wherein a topmost metal layer of the interconnect structure farthest from the substrate comprises aluminum; and
a through-substrate via (TSV) extending from the topmost metal layer of the interconnect structure to a backside of the substrate;
a first encapsulant around the first die;
a second RDS over the first encapsulant and the first die, wherein the TSV electrically couples the second RDS and the first RDS; and
a second die over and electrically coupled to the second RDS.

2. The package of claim 1, wherein a lower metal layer of the interconnect structure proximate to the substrate comprises copper.

3. The package of claim 2, wherein a first critical dimension (CD) of the first die is larger than a second CD of the second die.

4. The package of claim 3, wherein a third CD of the first RDS is larger than the first CD of the first die.

5. The package of claim 4, wherein the first RDS and the second RDS have a same critical dimension.

6. The package of claim 3, wherein the first die further comprises:
a passivation layer over the interconnect structure; and
a conductive pad embedded in the passivation layer, wherein the TSV is connected to the conductive pad.

7. The package of claim 6, wherein the first die further comprises a post-processing interconnect (PPI) over the passivation layer, wherein the interconnect structure is disposed between the PPI and the substrate, wherein the PPI comprises second dielectric layers and second electrically conductive features embedded in the second dielectric layers, wherein the second electrically conductive features are electrically coupled to the conductive pad.

8. The package of claim 7, wherein the device region of the first die comprises first electrical components, wherein the first electrical components comprise a transistor, wherein the PPI further comprises second electrical components embedded in the second dielectric layers, wherein the interconnect structure interconnects the second electrical components with the first electrical components to form functional circuits of the first die.

9. The package of claim 8, further comprising a package substrate, wherein a second side of the first RDS opposing the first side of the first RDS is bonded to the package substrate.

10. The package of claim 9, further comprising:
an underfill material between the second die and the second RDS; and
a second encapsulant over the second RDS and around the second die and the underfill material.

11. The package of claim 10, further comprising a heat sink attached to a first side of the second encapsulant distal from the second RDS.

12. A package comprising:
a first die comprising:
a substrate;
transistors at a front side of the substrate;
an interconnect structure at the front side of the substrate and electrically coupled to the transistors, wherein upper metal layers of the interconnect structure distal from the substrate comprise a first metal material, and lower metal layers of the interconnect structure proximate to the substrate comprise a second metal material different from the first metal material; and
a through-substrate via (TSV) extending through the substrate and connected to an uppermost metal layer of the interconnect structure;
a first molding material around the first die;
a first redistribution structure (RDS) under the first die and the first molding material, wherein the first RDS comprises first dielectric layers and first conductive features in the first dielectric layers;
a second RDS over the first die and the first molding material, wherein the second RDS comprises second dielectric layers and second conductive features in the second dielectric layers, wherein the TSV of the first die electrically couples the first RDS to the second RDS; and
a second die over and electrically coupled to the second RDS.

13. The package of claim 12, wherein a minimum line width of the second die is smaller than a minimum line width of the first die.

14. The package of claim 13, wherein the minimum line width of the first die is smaller than a minimum line width of the first RDS.

15. The package of claim 14, wherein the first dielectric layers of the first RDS comprise a non-organic material, wherein the second dielectric layers of the second RDS comprise an organic material, wherein the minimum line width of the first RDS is smaller than a minimum line width of the second RDS.

16. The package of claim 15, further comprising:
a third die over and electrically coupled to the second RDS; and
a local silicon interconnect (LSI) interposer embedded in the dielectric layers of the second RDS, wherein the LSI interposer comprises another substrate and a third RDS over the another substrate, wherein the second die is electrically coupled to the third die by the LSI interposer, wherein a minimum line width of the LSI interposer is a same as the minimum line width of the second die.

17. A method of forming a package, the method comprising:
forming a first redistribution structure (RDS) over a carrier, wherein the first RDS comprises first dielectric layers and first electrically conductive features embedded in the first dielectric layers;
bonding a first die to an upper surface of the first RDS distal from the carrier, wherein the first die is formed using a first process node;
forming an encapsulant on the upper surface of the first RDS around the first die;
forming a second RDS over the encapsulant and the first die, wherein the second RDS comprises second dielectric layers and second electrically conductive features embedded in the second dielectric layers; and
bonding a second die to an upper surface of the second RDS distal from the carrier, wherein the second die is formed using a second process node, wherein a first critical dimension (CD) of the first process node is different from a second CD of the second process node.

18. The method of claim 17, wherein the first CD is larger than the second CD, wherein the first RDS and the second RDS are formed using a third process node, wherein a third CD of the third process node is larger than the first CD.

19. The method of claim 17, wherein the first die is formed to include:
a substrate;
electrical components at a front side of the substrate;
an interconnect structure at the front side of the substrate, wherein the interconnect structure is over and electrically coupled to the electrical components, wherein a topmost conductive line of the interconnect structure distal from the substrate is formed of a first metal material, and a lower conductive line of the interconnect structure proximate to the substrate is formed of a second metal material different from the first metal material;
a conductive bump at a backside of the substrate; and
a through-substrate via (TSV) extending from the topmost conductive line of the interconnect structure to the conductive bump, wherein the TSV electrically couples the first RDS to the second RDS.

20. The method of claim 19, wherein the first metal material is aluminum, and the second metal material is copper.
